(19) United States
(12) Patent Application Publication
(10) Pub. No.: US 2025/0286532 A1
(43) Pub. Date: Sep. 11, 2025

(54) Bulk Acoustic Resonator and Electrode Design Method for the Bulk Acoustic Resonator

(71) Applicant: Wuhan MEMSonics Technologies Co., Ltd., Wuhan (CN)

(72) Inventors: Jie ZHOU, Wuhan (CN); Yao CAI, Wuhan (CN); Yang ZOU, Wuhan (CN); Binghui LIN, Wuhan (CN); Chengliang SUN, Wuhan (CN); Bowoon SOON, Singapore (SG); Jian WANG, Wuhan (CN)

(21) Appl. No.: 18/981,224

(22) Filed: Dec. 13, 2024

(30) Foreign Application Priority Data
Mar. 7, 2024 (CN) 202410263234.9

(51) Int. Cl. H03H 9/13; G06F 30/10

(52) U.S. Cl. CPC H03H 9/132; G06F 30/10

(57) ABSTRACT

The present disclosure relates to the technical field of resonators. Provided are a bulk acoustic resonator and an electrode design method for the bulk acoustic resonator. The bulk acoustic resonator includes a substrate, and a bottom electrode, a piezoelectric layer and a top electrode laminated on the substrate in sequence. The bottom electrode and/or the top electrode have orthographic projections on the substrate, the profile of the orthographic projections is formed by sequentially connecting a plurality of curve segments end to end, the plurality of curve segments are all intercepted from line segments near non-endpoints of a plurality of Bezier curves, and the order of the Bezier curves is equal to or greater than 2.

### CROSS-REFERENCE TO RELATED APPLICATION

The present disclosure claims the priority of Chinese Patent Application No. 202410263234.9, filed with the China National Intellectual Property Administration on Mar. 7, 2024 and entitled “bulk acoustic resonator and an electrode design method for the bulk acoustic resonator”, which is incorporated herein by reference in its entirety.

### TECHNICAL FIELD

The present disclosure relates to the technical field of resonators, and in particular to a bulk acoustic resonator and an electrode design method for the bulk acoustic resonator.

### BACKGROUND

Radio frequency filters are widely applied in military and civilian fields such as radar communications and radio frequency front ends. A film bulk acoustic resonator (FBAR) becomes one of key components for building a radio frequency bandpass filter due to the performance of high quality factor, low loss, high reliability, miniaturization, etc.

The working principle of the FBAR is applying a radio frequency electrical signal by means of an upper electrode and a lower electrode, converting the electrical signal into high frequency vibrations of a film by using inverse piezoelectric effect of a piezoelectric material, and generating an acoustic wave signal. The FBAR mainly generates longitudinal waves that propagate in the thickness direction, and inevitably, transverse acoustic waves may also exist. The transverse acoustic waves tend to reflect continuously at boundaries to form standing waves, thereby forming ripples in an impedance curve of a resonator, i.e. generating a pseudo-mode, and thus reducing the performance of the resonator. Therefore, it is necessary to reasonably design the shape of an electrode in the resonator, so as to alleviate the pseudo-mode caused by the transverse acoustic waves.

In the related art, an irregular pentagon is generally used as a main electrode shape, and this electrode shape increases the reflection distance of transverse acoustic waves by using non-parallel boundaries, thereby alleviating a pseudo-mode caused by the transverse acoustic waves. However, with the continuous development of radio frequency technologies, the existing resonators that use an irregular pentagon as the electrode shape cannot meet the requirements.

### SUMMARY

An object of some embodiments of the present disclosure is to provide a bulk acoustic resonator and an electrode design method for the bulk acoustic resonator.

In order to achieve the described object, embodiments of the present disclosure use the following technical solutions:
an aspect of embodiments of the present disclosure provides a bulk acoustic resonator, including a substrate, and a bottom electrode, a piezoelectric layer and a top electrode laminated on the substrate in sequence, the bottom electrode and/or the top electrode having orthographic projections on the substrate, a profile of the orthographic projections being formed by sequentially connecting a plurality of curve segments end to end, the plurality of curve segments all being intercepted from line segments near non-endpoints of a plurality of Bezier curves, and the order of the Bezier curves being equal to or greater than 2.

In some embodiments, each of the Bezier curves includes a start control point, at least one intermediate control point and an end control point, the start control point, the intermediate control points and the end control point of each of the Bezier curves are all some or all vertices of a preset polygon, and the start control points of the plurality of Bezier curves are sequentially selected from all the vertices of the preset polygon.

In some embodiments, the preset polygon does not have parallel sides.

In some embodiments, the radii of curvature of respective curvature circles of two adjacent curve segments at a same connection point are equal.

In some embodiments, when the order of the Bezier curves is greater than 2, the number of the plurality of curve segments is equal to or greater than the number of the plurality of Bezier curves.

In some embodiments, when the order of the Bezier curves is equal to 2, the number of the plurality of curve segments is equal to the number of the plurality of Bezier curves.

Another aspect of embodiments of the present disclosure provides an electrode design method for a bulk acoustic resonator, the method including:
a plurality of Bezier curves intersecting with each other and intersection points in the plurality of Bezier curves are acquired, wherein the intersection points do not include endpoints of the Bezier curves, and the order of the Bezier curves is equal to or greater than 2;
line segments near non-endpoints of the Bezier curves are determined according to the intersection points; and
some or all of the line segments near the non-endpoints that are sequentially connected end to end at the intersection points are selected from the line segments near the non-endpoints of the plurality of Bezier curves to serve as a plurality of curve segments, such that the plurality of curve segments are sequentially connected end to end to form an electrode profile.

In some embodiments, the plurality of Bezier curves intersecting with each other and the intersection points in the plurality of Bezier curves being acquired includes:
a preset polygon and vertices of the preset polygon are acquired;
some or all vertices of the preset polygon are selected to serve as a start control point, at least one intermediate control point and an end control point of each of the Bezier curves, the start control points of the plurality of the Bezier curves being sequentially selected from all the vertices of the preset polygon; and
a plurality of Bezier curves intersecting with each other are constructed according to the start control point, the at least one intermediate control point and the end control point of each of the Bezier curves, and intersection points in the plurality of Bezier curves are determined.

In some embodiments, the preset polygon does not have parallel sides.

In some embodiments, the radii of curvature of respective curvature circles of two adjacent curve segments at the same connection point are equal.

### BRIEF DESCRIPTION OF THE DRAWINGS

In order to describe the technical solutions in the embodiments of the present disclosure more clearly, hereinafter, accompanying drawings requiring to be used in the embodiments are introduced briefly. It should be understood that the following accompanying drawings only illustrate some embodiments of the present disclosure, and therefore shall not be considered as limiting the scope. For a person of ordinary skill in the art, other related accompanying drawings can also be obtained according to these accompany drawings without involving any inventive effort.

FIG. 1 is a first schematic diagram of an electrode design process provided according to embodiments of the present disclosure;

FIG. 2 is a first schematic structural diagram of an electrode profile provided according to embodiments of the present disclosure;

FIG. 3 is a second schematic diagram of an electrode design process provided according to embodiments of the present disclosure;

FIG. 4 is a second schematic structural diagram of an electrode profile provided according to embodiments of the present disclosure;

FIG. 5 is a third schematic diagram of an electrode design process provided according to embodiments of the present disclosure;

FIG. 6 is a third schematic structural diagram of an electrode profile provided according to embodiments of the present disclosure;

FIG. 7 is a fourth schematic structural diagram of an electrode profile provided according to embodiments of the present disclosure; and

FIG. 8 is a schematic diagram of respective impedance curves of an existing bulk acoustic resonator using a pentagonal electrode profile and a bulk acoustic resonator using the electrode profile shown in FIG. 6 according to embodiments of the present disclosure.

110—preset polygon; 10—electrode profile; 11—first middle line segment; 12—second middle line segment; 13—third middle line segment; 14—fourth middle line segment; 15—fifth middle line segment; 16—sixth middle line segment; 17—seventh middle line segment; 18—eighth middle line segment; 19—ninth intermediate line segment; 20—tenth intermediate line segment; 21—eleventh intermediate line segment; 22—twelfth intermediate line segment; 23—thirteenth middle line segment; 24—fourteenth middle line segment; 25—fifteenth middle line segment; 26—sixteenth middle line segment; 27—seventeenth middle line segment; 28—eighteenth middle line segment; 29—nineteenth middle line segment; 30—twentieth middle line segment; 31—twenty-first middle line segment.

### DETAILED DESCRIPTION OF THE EMBODIMENTS

To make the objects, technical solutions and advantages of the embodiments of the present disclosure clearer, hereinafter, the technical solutions in the embodiments of the present disclosure will be described clearly and thoroughly with reference to the accompanying drawings of the embodiments of the present disclosure. Obviously, the embodiments as described are some of the embodiments of the present disclosure, and are not all of the embodiments. Generally, components of embodiments of the present disclosure as described and illustrated in the accompanying drawings herein may be arranged and designed in various different configurations.

Therefore, the following detailed description of embodiments of the present disclosure provided in the accompanying drawings is not intended to limit the scope of protection of the present disclosure, but merely represent selected embodiments of the present disclosure. It should be noted that features in the embodiments of the present disclosure may be combined with one another without conflicts, and the combined embodiments still fall within the scope of protection of the present disclosure.

It should be noted that similar numerals and letters represent similar items in the following accompanying drawings, and thus once a certain item is defined in one accompanying drawing, it does not need to be further defined and explained in subsequent accompanying drawings.

In the description of some embodiments of the present disclosure, it should be noted that orientation or positional relationships indicated by terms such as “center”, “upper”, “lower”, “left”, “right”, “vertical”, “horizontal”, “inner”, “outer”, etc. are orientation or positional relationships based on those as shown in the accompanying drawings, or based on orientation or positional relationships of a product of the present disclosure which is conventionally placed during use, and are only used to facilitate the description of some embodiments of the present disclosure and to simplify the description, rather than indicating or implying that an apparatus or element referred to must have a specific orientation, and be constructed and operated in the specific orientation, and therefore said terms cannot be understood as limiting some embodiments of the present disclosure. In addition, the terms “first”, “second”, “third” and the like are used for distinguished description only and cannot be construed as indicating or implying relative importance.

Furthermore, the terms “horizontal”, “vertical”, etc. do not imply that a component needs to be absolutely horizontal or vertical, but may be slightly oblique. For example, “horizontal” merely means that the direction thereof is more horizontal relative to “vertical”, and does not mean that the structure must be completely horizontal, but may be slightly oblique.

In the description of some embodiments of the present disclosure, it should be further noted that unless specified and limited otherwise, the terms “provide”, “mount”, “connect to”, and “connecting” should be understood broadly, and for example, may be fixed connection, and may also be detachable connection, or integral connection; may be mechanical connection, and may also be electrical connection; and may be direct connection, and may also be indirect connection by means of an intermediate medium, and may also be interior communication between two elements. For a person of ordinary skill in the art, specific meanings of the described terms in some embodiments of the present disclosure could be understood according to specific situations.

Embodiments of the present disclosure provide a bulk acoustic resonator. An electrode shape used by the bulk acoustic resonator can further alleviate a pseudo-mode caused by transverse acoustic waves, and thus effectively improve the performance of the bulk acoustic resonator, so that a filter built thereby can meet higher radio frequency requirements.

In order to optimize a pseudo-mode caused by transverse acoustic waves, it is necessary to design the shape of an electrode in a bulk acoustic resonator. An electrode design method for a bulk acoustic resonator is provided herewith. The method includes:
S1: a plurality of Bezier curves intersecting with each other and intersection points in the plurality of Bezier curves are acquired, wherein the intersection points do not include endpoints of the Bezier curves, and the order of the Bezier curves is equal to or greater than 2.

Bezier curves can be introduced in the process of designing the shape of an electrode, and thus, the irregularity can be improved, and the Bezier curves are also relatively smooth and do not have a sharp corner. The Bezier curves may be controlled by multiple points. When points P₀, P₁, . . . and Pₙ are given, a general parameter formula of the Bezier curves is:

$$\begin{matrix}a . B ( t ) = {\sum }_{i = 0}^{n} ( \begin{matrix}n \\ i\end{matrix} ) {{P}_{i} ( 1 - t )}^{n - i} {t}^{i} \\ b . ( \begin{matrix}n \\ i\end{matrix} ) = \frac{n !}{i ! ( n - 1 ) !}\end{matrix}$$

where t∈[0,1], and the point Pᵢ represents control points of the Bezier curves. A Bezier polygon is formed by connecting the control points of the Bezier curves with lines, and starts at P₀ and ends at Pₙ. The shape of the Bezier curves and the shape of the Bezier polygon can be reasonably designed by controlling the positions of the given points P₀, P₁, . . . and Pₙ.

Parameter n represents the order control number of the Bezier curves. When n is equal to 1, the control points are P₀ and P₁ (P₀ is a start control point, and P₁ is an end control point), and the order of the Bezier curves is 1, i.e. a line segment.

When n is equal to 2, the control points are P₀, P₁ and P₂ (P₀ is the start control point, and P₂ is the end control point), the order of the Bezier curves is 2, and a general parameter formula of the Bezier curves is:

$$B ( t ) = {( 1 - t )}^{2} {P}_{0} + 2 {t ( 1 - t )}^{2} {P}_{1} + {t}^{2} {P}_{2}$$

where t∈[0,1].

When n is greater than or equal to 3, the control points are P₀, P₁, P₂ and P₃ (P₀ is the start control point, and P₃ is the end control point), the order of the Bezier curves is 3, and a general parameter formula of the Bezier curves is:

$$B ( t ) = {( 1 - t )}^{3} {P}_{0} + 3 {t ( 1 - t )}^{2} {P}_{1} + 3 {t}^{2} ( 1 - t ) {P}_{2} + {t}^{3} {P}_{3}$$

where t∈[0,1].

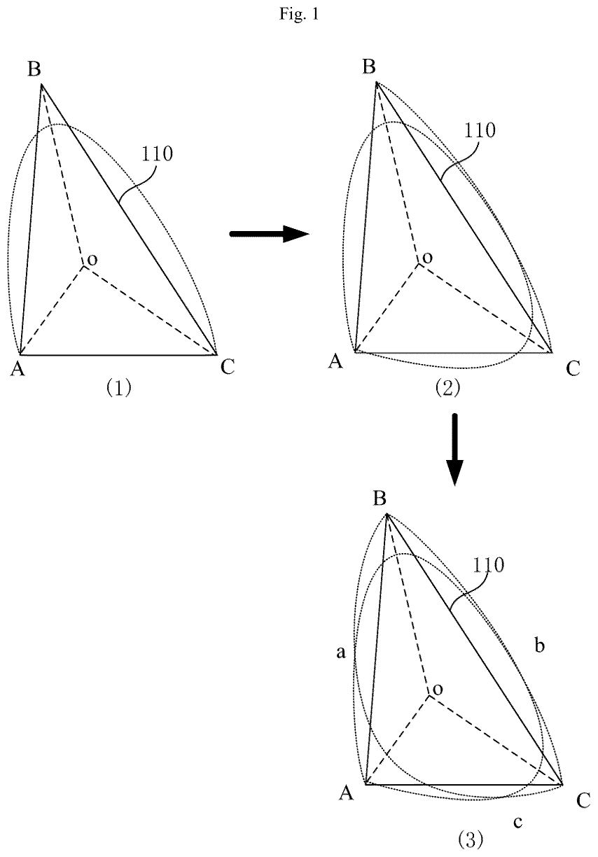

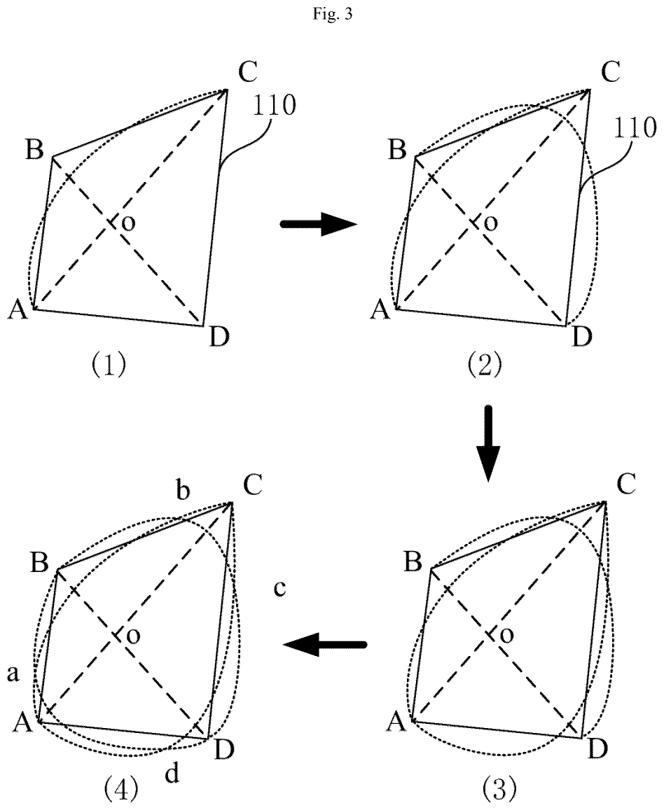

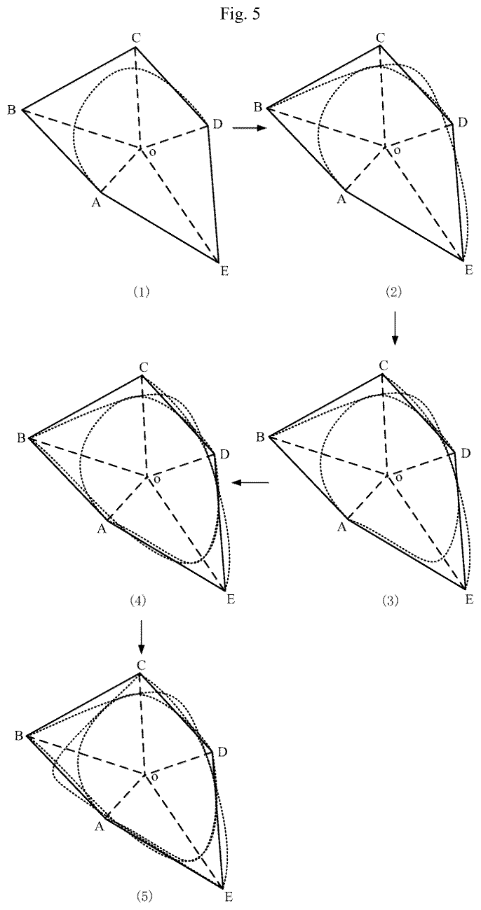

Please refer to (3) of FIG. 1, (4) of FIG. 3 or (5) of FIG. 5, a plurality of Bezier curves are acquired or obtained first, and the orders of all the Bezier curves are greater than or equal to 2, so that the number of control points of each Bezier curve is equal to or greater than 3. The plurality of Bezier curves intersect with each other, so as to form an intersection point at each intersection position, and each Bezier curve has at least two intersection points. Certainly, the intersection points do not include two endpoints of each Bezier curve.

Specifically, for example, (3) of FIG. 1 shows three second-order Bezier curves, and the control points of the three Bezier curves are ABC (point A is the start control point, point B is an intermediate control point, and point C is the end control point), BCA (point B is the start control point, point C is the intermediate control point, and point A is the end control point) and CAB (point C is the start control point, point A is the intermediate control point, and point B is the end control point), respectively. Correspondingly, the three Bezier curves intersect with each other to form three intersection points a, b and c, and each of the Bezier curves has two intersection points. Since the three points, i.e. A, B and C, sequentially serve as the endpoints of the three Bezier curves, the intersection points do not include any one of the points A, B and C.

Alternatively, for example, (4) of FIG. 3 shows four second-order Bezier curves, and the control points of the four Bezier curves are ABC (point A is the start control point, point B is the intermediate control point, and point C is the end control point), BCD (point B is the start control point, point C is the intermediate control point, and point D is the end control point), CDA (point C is the start control point, point D is the intermediate control point, and point A is the end control point) and DAB (point D is the start control point, point A is the intermediate control point, and point B is the end control point), respectively. Correspondingly, the four Bezier curves intersect with each other to form four intersection points a, b, c and d. Each of the Bezier curves has two intersection points. Since the four points, i.e. A, B, C and D, sequentially serve as the endpoints of the four Bezier curves, the intersection points do not include any one of the points A, B, C and D. For ease of understanding and distinguishing, all control points of a Bezier curve are used to represent the corresponding Bezier curve subsequently. For example, when the control points of a second-order Bezier curve is ABC, a Bezier curve ABC is used to refer to the second-order Bezier curve.

Alternatively, for another example, (5) of FIG. 5 shows five third-order Bezier curves, and the control points of the five Bezier curves are ABCD (point A is the start control point, points B and C are the intermediate control points, and point D is the end control point), BCDE (point B is the start control point, points C and D are the intermediate control points, and point E is the end control point), CDEA (point C is the start control point, points D and E are the intermediate control points, and point A is the end control point), DEAB (point D is the start control point, points E and A are the intermediate control points, and point B is the end control point) and EABC (point E is the start control point, points A and B are the intermediate control points, and point C is the end control point), respectively. Correspondingly, the five Bezier curves intersect with each other to form a plurality of intersection points, for example, at least including points a, b, c, d and e. Each of the Bezier curves has at least two intersection points. Since the five points, i.e. A, B, C, D and E, sequentially serve as the endpoints of the five Bezier curves, the intersection points do not include any one of the points A, B, C, D and E.
S2: line segments near non-endpoints of the Bezier curves are determined according to the intersection points.

According to the intersection points obtained above and each of the Bezier curves having at least two intersection points, at least one line segment near the non-endpoints can be intercepted from each Bezier curve by using two adjacent intersection points. In other words, each line segment near the non-endpoints belongs to one segment of a Bezier curve from which the line segment is intercepted. The line segment near the non-endpoints refers to a line segment that does not include the two endpoints of the Bezier curve, and therefore may also be referred to as a middle line segment.

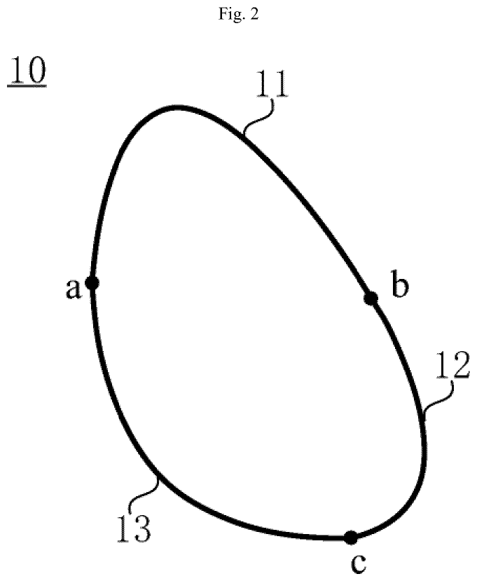

Specifically, for example, in (3) of FIG. 1, a middle line segment can be intercepted or determined from the Bezier curve ABC by using the intersection points a to b, and the middle line segment can be represented by using a first middle line segment 11 in FIG. 2. By the same reasoning, a middle line segment can be intercepted or determined from the Bezier curve BCA by using the intersection points b to c, and the middle line segment can be represented by using a second middle line segment 12 in FIG. 2. A middle line segment can be intercepted or determined from the Bezier curve CAB by using the intersection points c to a, and the middle line segment can be represented by using a third middle line segment 13 in FIG. 2.

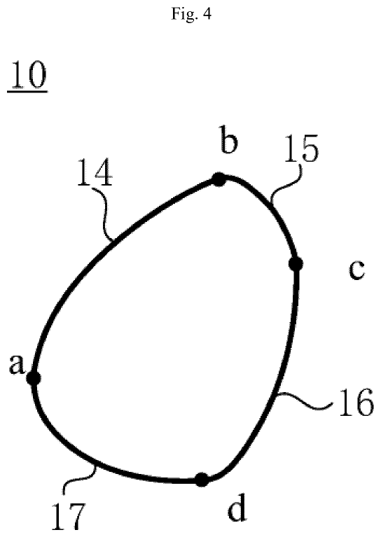

Alternatively, for example, in (4) of FIG. 3, a middle line segment can be intercepted or determined from the Bezier curve ABC by using the intersection points a to b, and the middle line segment can be represented by using a fourth middle line segment 14 in FIG. 4. By the same reasoning, a middle line segment can be intercepted or determined from the Bezier curve BCD by using the intersection points b to c, and the middle line segment can be represented by using a fifth middle line segment 15 in FIG. 4. A middle line segment can be intercepted or identified from the Bezier curve CDA by using the intersection points c to d, and the middle line segment can be represented by using a sixth middle line segment 16 in FIG. 4. A middle line segment can be intercepted or determined from the Bezier curve DAB by using the intersection points d to a, and the middle line segment can be represented by using a seventh middle line segment 17 in FIG. 4.

Alternatively, for another example, in (5) of FIG. 5, the same Bezier curve may have two or more intersecting points, for example, the Bezier curve ABCD has four intersecting points. Thus, three middle line segments can be intercepted or identified from the Bezier curve ABCD by using the four intersection points. For the Bezier curve BCDE, the Bezier curve CDEA, the Bezier curve DEAB and the Bezier curve EABC, a plurality of intersection points can be determined according to actual situations, and then at least one middle line segment is intercepted or determined from each Bezier curve.
S3: some or all of the line segments near the non-endpoints that are sequentially connected end to end at the intersection points are selected from the line segments near the non-endpoints of the plurality of Bezier curves to serve as a plurality of curve segments, such that the plurality of curve segments are sequentially connected end to end to form an electrode profile 10.

All or some of the middle line segments obtained in S2 can be selected to serve as the curve segments. In the selection process, the selected middle line segments need to satisfy the requirement of being sequentially connected end to end at the intersection points to form a closed loop. In this way, it is convenient for the selected plurality of curve segments to be sequentially connected end to end to form a closed loop, and the shape serves as the electrode profile 10.

Specifically, for example, all the middle line segments, i.e. the first middle line segment 11, the second middle line segment 12 and the third middle line segment 13, are selected from (3) of FIG. 1 to serve as the curve segments, respectively, so as to obtain the electrode profile 10 shown in FIG. 2.

Alternatively, for example, all the middle line segments, i.e. the fourth middle line segment 14, the fifth middle line segment 15, the sixth middle line segment 16 and the seventh middle line segment 17, are selected from (4) of FIG. 3 to serve as the curve segments, respectively, so as to obtain the electrode profile 10 shown in FIG. 4.

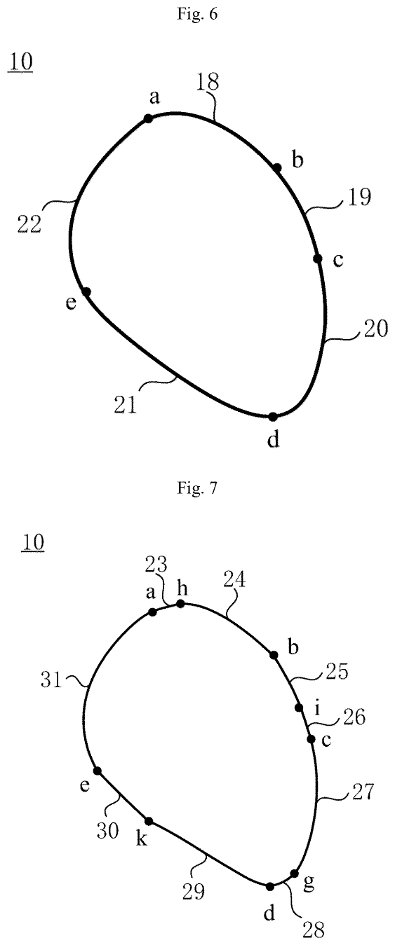

Alternatively, for another example, some of the middle line segments are selected from (5) of FIG. 5, and with reference to FIG. 6, for example, an eighth middle line segment 18, a ninth middle line segment 19, a tenth middle line segment 20, an eleventh middle line segment 21 and a twelfth middle line segment 22 are selected to serve as the curve segments, respectively, so as to obtain the electrode profile 10 shown in FIG. 6. Certainly, reference can also be made to FIG. 7, for example, a thirteenth middle line segment 23, a fourteenth middle line segment 24, a fifteenth middle line segment 25, a sixteenth middle line segment 26, a seventeenth middle line segment 27, an eighteenth middle line segment 28, a nineteenth middle line segment 29, a twentieth middle line segment 30 and a twenty-first middle line segment 31 are selected to serve as the curve segments, respectively, so as to obtain the electrode profile 10 shown in FIG. 7.

The electrode profile 10 obtained according to this can have a high degree of irregularity, and in particular, after further optimization based on Bezier curves, the finally obtained electrode profile 10 can further suppress pseudo-modes, so that the bulk acoustic resonator has good performance.

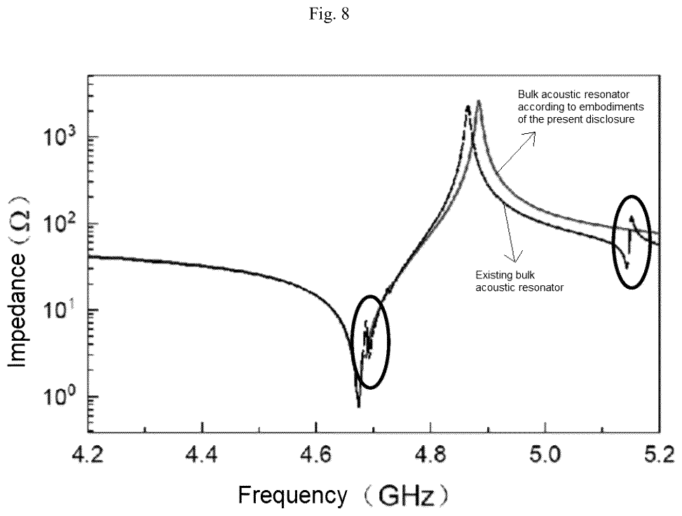

As shown in FIG. 8, respective impedance curves of an existing bulk acoustic resonator using a pentagonal electrode profile 10 and a bulk acoustic resonator using the electrode profile 10 shown in FIG. 6 according to embodiments of the present disclosure are respectively shown. It can be determined from the two elliptical circles in FIG. 8 that there are few ripples on the impedance curve of the bulk acoustic resonator according to embodiments of the present disclosure, so that the pseudo-modes can be effectively suppressed.

In some embodiments, when a plurality of Bezier curves intersecting with each other and intersection points in the plurality of Bezier curves are acquired in S1, a preset polygon 110 may be introduced, and vertices of the preset polygon 110 are sequentially used as control points of the Bezier curves, so as to obtain the plurality of Bezier curves intersecting with each other. Specifically, the step includes:
S1.1: a preset polygon 110 and vertices of the preset polygon 110 are acquired.

The preset polygon 110 is acquired first, and thus a plurality of vertices thereof can be obtained according to preset polygon 110.

For example, the preset polygon 110 shown in (1) of FIG. 1 is a triangle, and accordingly, the triangle has three vertices A, B and C.

Alternatively, for example, the preset polygon 110 shown in (1) of FIG. 3 is a quadrangle, and accordingly, the quadrangle has four vertices A, B, C and D.

Alternatively, for another example, the preset polygon 110 shown in (1) of FIG. 5 is a pentagon, and accordingly, the pentagon has five vertices A, B, C, D and E.
S1.2: some or all vertices of the preset polygon 110 are selected to serve as a start control point, at least one intermediate control point and an end control point of each of the Bezier curves, the start control points of the plurality of the Bezier curves being sequentially selected from all the vertices of the preset polygon 110.

After the specific shape of the preset polygon 110 is determined in S1.1, some or all of the vertices of the preset polygon 110 may be selected, and the selected vertices are used as a start control point, at least one intermediate control point and an end control point of each of the Bezier curves. In order to construct different Bezier curves and to achieve that the finally constructed plurality of Bezier curves can intersect with each other to form the described middle line segments (which can be used to form the electrode profile 10), the next Bezier curve can be offset by one vertex in a clockwise or counterclockwise direction during point selection. That is, the start control points of the plurality of Bezier curves are sequentially selected from all the vertices of the preset polygon 110.

Specifically, for example, as shown in (1) of FIG. 1, the preset polygon 110 is a triangle. As the order of the Bezier curves needs to be equal to or greater than 2, second-order Bezier curves (three control points) are selected. Therefore, all the vertices of the triangle are selected when the Bezier curves are constructed. When the start control point of a first Bezier curve is selected, point A is selected, and correspondingly, point B is selected as the intermediate control point and point C is selected as the end control point in sequence. Next, with reference to (2) of FIG. 1, when the start control point of a second Bezier curve is selected, point B is selected in a clockwise direction, and correspondingly, point C is selected as the intermediate control point and point A is selected as the end control point in sequence. Finally, with reference to (3) of FIG. 1, when the start control point of a third Bezier curve is selected, point C is selected in a clockwise direction, and correspondingly, point A is selected as the intermediate control point and point B is selected as the end control point in sequence.

Alternatively, for example, as shown in (1) of FIG. 3, the preset polygon 110 is a quadrangle, and second-order Bezier curves are selected. Therefore, three of four vertices of the quadrangle may be selected to serve as the control points of the same Bezier curve (certainly, in other embodiments, third-order Bezier curves may also be selected, and correspondingly, all vertices of the quadrangle need to be selected when the Bezier curves are constructed). Firstly, as shown in (1) of FIG. 3, when the start control point of a first Bezier curve is selected, point A is selected, and correspondingly, point B is selected as the intermediate control point and point C is selected as the end control point in sequence. Then, with reference to (2) of FIG. 3, when the start control point of a second Bezier curve is selected, point B is selected in a clockwise direction, and correspondingly, point C is selected as the intermediate control point and point D is selected as the end control point in sequence. Next, with reference to (3) of FIG. 3, when the start control point of a third Bezier curve is selected, point C is selected in a clockwise direction, and correspondingly, point D is selected as the intermediate control point and point A is selected as the end control point in sequence. Finally, with reference to (4) of FIG. 3, when the start control point of a fourth Bezier curve is selected, point D is selected in a clockwise direction, and correspondingly, point A is selected as the intermediate control point and point B is selected as the end control point in sequence.

Alternatively, for another example, as shown in FIG. 5, the preset polygon 110 is a pentagon, and third-order Bezier curves are selected. Therefore, four of five vertices of the pentagon may be selected to serve as the control points of the same Bezier curve (certainly, in other embodiments, second-order or fourth-order Bezier curves may also be selected, and correspondingly, three vertices or all the vertices of the pentagon need to be selected when the Bezier curves are constructed). Firstly, as shown in (1) of FIG. 5, when the start control point of a first Bezier curve is selected, point A is selected, and correspondingly, points B and C are selected as the intermediate control points and point D is selected as the end control point in sequence. Then, with reference to (2) of FIG. 5, when the start control point of a second Bezier curve is selected, point B is selected in a clockwise direction, and correspondingly, points C and D are selected as the intermediate control points and point E is selected as the end control point in sequence. Next, with reference to (3) of FIG. 5, when the start control point of a third Bezier curve is selected, point C is selected in a clockwise direction, and correspondingly, points D and E are selected as the intermediate control points and point A is selected as the end control point in sequence. Next, with reference to (4) of FIG. 5, when the start control point of a fourth Bezier curve is selected, point D is selected in a clockwise direction, and correspondingly, points E and A are selected as the intermediate control points and point B is selected as the end control point in sequence. Finally, with reference to (5) of FIG. 5, when the start control point of a fifth Bezier curve is selected, point E is selected in a clockwise direction, and correspondingly, points A and B are selected as the intermediate control points and point C is selected as the end control point in sequence.
S1.3: a plurality of Bezier curves intersecting with each other are constructed according to the start control point, the at least one intermediate control point and the end control point of each of the Bezier curves, and intersection points in the plurality of Bezier curves are determined.

According to the determined control points of each of the Bezier curves, a plurality of Bezier curves intersecting with each other can be constructed. In addition, intersection points are determined according to the intersection situation.

Specifically, for example, with reference to (1) to (3) of FIG. 1, a Bezier curve ABC, a Bezier curve BCA and a Bezier curve CAB can be obtained in sequence. As shown in (3) of FIG. 1 and FIG. 2, intersection points a, b and c are obtained according to the Bezier curve ABC, the Bezier curve BCA and the Bezier curve CAB.

Alternatively, for example, as shown in (1) to (4) of FIG. 3, a Bezier curve ABC, a Bezier curve BCD, a Bezier curve CDA and a Bezier curve DAB can be obtained in sequence. As shown in (4) of FIG. 3 and FIG. 4, intersection points a, b, c and d are obtained according to the Bezier curve ABC, the Bezier curve BCD, the Bezier curve CDA and the Bezier curve DAB.

Alternatively, for another example, as shown in (1) to (5) of FIG. 5, a Bezier curve ABCD, a Bezier curve BCDE, a Bezier curve CDEA, a Bezier curve DEAB and a Bezier curve EABC can be obtained in sequence. As shown in FIG. 6, some intersection points a, b, c, d and e are selected according to the Bezier curve ABCD, the Bezier curve BCDE, the Bezier curve CDEA, the Bezier curve DEAB and the Bezier curve EABC. Alternatively, as shown in FIG. 7, some intersection points a, b, c, d, e, h, i, g and k are selected according to a Bezier curve ABCD, a Bezier curve BCDE, a Bezier curve CDEA, a Bezier curve DEAB and a Bezier curve EABC.

In some embodiments, the preset polygon 110 does not have parallel sides, for example, as shown in FIG. 1, FIG. 3 or FIG. 5, none of the triangle, the quadrangle and the pentagon has any two parallel sides, and in this way, the irregularity of a final electrode profile 10 can be improved.

In some embodiments, the radii of curvature of respective curvature circles of two adjacent curve segments at the same connection point are equal. Thus, a sharp corner at the intersection point (i.e. the connecting point of two curve segments) of two curve segments can be avoided, which helps to improve the performance of a resonator and also facilitates processing. For example, in FIG. 2, the first middle line segment 11 and the second middle line segment 12 are tangent to each other at the intersection point b, so that the radii of curvature of respective curvature circles of the first middle line segment 11 and the second middle line segment 12 at the point b are equal. By the same reasoning, the two curve segments at the points c and a also satisfy the characteristics of tangency. FIGS. 4, 6 and 7 show the same principle.

In some embodiments, the electrode profile 10 does not have a concave edge. So that an electromechanical coupling factor of a resonator can be increased.

An aspect of embodiments of the present disclosure provides a bulk acoustic resonator. An electrode of the bulk acoustic resonator can be obtained according to the method above.

An aspect of embodiments of the present disclosure provides a bulk acoustic resonator, including a substrate, and a bottom electrode, a piezoelectric layer and a top electrode laminated on the substrate in sequence. When an electrode profile 10 is designed, an electrode profile 10 of the bottom electrode may be designed, an electrode profile 10 of the top electrode may also be designed, and the electrode profiles 10 of the bottom electrode and the top electrode may also be designed at the same time.

An electrode to be designed has an orthographic projection on the substrate in the thickness direction of the substrate, and the profile of the orthographic projection is the profile of the electrode. The profile of the orthographic projection is formed by sequentially connecting a plurality of curve segments end to end, the plurality of curve segments are all intercepted from middle line segments of a plurality of Bezier curves, and the order of the Bezier curves is equal to or greater than 2. On the basis of the relevant description in the method above, this electrode profile 10 can have a high degree of irregularity, and in particular, after further optimization based on Bezier curves, the finally obtained electrode profile 10 can further suppress pseudo-modes, so that the bulk acoustic resonator has good performance.

In some embodiments, each of the Bezier curves includes a start control point, at least one intermediate control point and an end control point, the start control point, the intermediate control points and the end control point of each of the Bezier curves are all some or all vertices of a preset polygon 110, and the start control points of the plurality of Bezier curves are sequentially selected from all the vertices of the preset polygon 110.

Specifically, the preset polygon 110 is acquired first, and thus a plurality of vertices thereof can be obtained according to the preset polygon 110.

For example, the preset polygon 110 shown in (1) of FIG. 1 is a triangle, and accordingly, the triangle has three vertices A, B and C.

Alternatively, for example, the preset polygon 110 shown in (1) of FIG. 3 is a quadrangle, and accordingly, the quadrangle has four vertices A, B, C and D.

Alternatively, for another example, the preset polygon 110 shown in (1) of FIG. 5 is a pentagon, and accordingly, the pentagon has five vertices A, B, C, D and E.

After the specific shape of the preset polygon 110 is determined, some or all of the vertices of the preset polygon 110 may be selected, and the selected vertices are used as a start control point, at least one intermediate control point and an end control point of each of the Bezier curves. In order to construct different Bezier curves and to achieve that the finally constructed plurality of Bezier curves can intersect with each other to form the described middle line segments (which can be used to form the electrode profile 10), the next Bezier curve can be offset by one vertex in a clockwise or counterclockwise direction during point selection. That is, the start control points of the plurality of Bezier curves are sequentially selected from all the vertices of the preset polygon 110.

Specifically, for example, as shown in (1) of FIG. 1, the preset polygon 110 is a triangle. As the order of the Bezier curves needs to be equal to or greater than 2, second-order Bezier curves (three control points) are selected. Therefore, all the vertices of the triangle are selected when the Bezier curves are constructed. When the start control point of a first Bezier curve is selected, point A is selected, and correspondingly, point B is selected as the intermediate control point and point C is selected as the end control point in sequence. Next, with reference to (2) of FIG. 1, when the start control point of a second Bezier curve is selected, point B is selected in a clockwise direction, and correspondingly, point C is selected as the intermediate control point and point A is selected as the end control point in sequence. Finally, with reference to (3) of FIG. 1, when the start control point of a third Bezier curve is selected, point C is selected in a clockwise direction, and correspondingly, point A is selected as the intermediate control point and point B is selected as the end control point in sequence.

Alternatively, for example, as shown in (1) of FIG. 3, the preset polygon 110 is a quadrangle, and second-order Bezier curves are selected. Therefore, three of four vertices of the quadrangle may be selected to serve as the control points of the same Bezier curve (certainly, in other embodiments, third-order Bezier curves may also be selected, and correspondingly, all vertices of the quadrangle need to be selected when the Bezier curves are constructed). Firstly, as shown in (1) of FIG. 3, when the start control point of a first Bezier curve is selected, point A is selected, and correspondingly, point B is selected as the intermediate control point and point C is selected as the end control point in sequence. Then, with reference to (2) of FIG. 3, when the start control point of a second Bezier curve is selected, point B is selected in a clockwise direction, and correspondingly, point C is selected as the intermediate control point and point D is selected as the end control point in sequence. Next, with reference to (3) of FIG. 3, when the start control point of a third Bezier curve is selected, point C is selected in a clockwise direction, and correspondingly, point D is selected as the intermediate control point and point A is selected as the end control point in sequence. Finally, with reference to (4) of FIG. 3, when the start control point of a fourth Bezier curve is selected, point D is selected in a clockwise direction, and correspondingly, point A is selected as the intermediate control point and point B is selected as the end control point in sequence.

Alternatively, for another example, as shown in FIG. 5, the preset polygon 110 is a pentagon, and third-order Bezier curves are selected. Therefore, four of five vertices of the pentagon may be selected to serve as the control points of the same Bezier curve (certainly, in other embodiments, second-order or fourth-order Bezier curves may also be selected, and correspondingly, three vertices or all the vertices of the pentagon need to be selected when the Bezier curves are constructed). Firstly, as shown in (1) of FIG. 5, when the start control point of a first Bezier curve is selected, point A is selected, and correspondingly, points B and C are selected as the intermediate control points and point D is selected as the end control point in sequence. Then, with reference to (2) of FIG. 5, when the start control point of a second Bezier curve is selected, point B is selected in a clockwise direction, and correspondingly, points C and D are selected as the intermediate control points and point E is selected as the end control point in sequence. Next, with reference to (3) of FIG. 5, when the start control point of a third Bezier curve is selected, point C is selected in a clockwise direction, and correspondingly, points D and E are selected as the intermediate control points and point A is selected as the end control point in sequence. Next, with reference to (4) of FIG. 5, when the start control point of a fourth Bezier curve is selected, point D is selected in a clockwise direction, and correspondingly, points E and A are selected as the intermediate control points and point B is selected as the end control point in sequence. Finally, with reference to (5) of FIG. 5, when the start control point of a fifth Bezier curve is selected, point E is selected in a clockwise direction, and correspondingly, points A and B are selected as the intermediate control points and point C is selected as the end control point in sequence.

According to the determined control points of each of the Bezier curves, a plurality of Bezier curves intersecting with each other can be constructed. In addition, intersection points are determined according to the intersection situation.

Specifically, for example, with reference to (1) to (3) of FIG. 1, a Bezier curve ABC, a Bezier curve BCA and a Bezier curve CAB can be obtained in sequence. As shown in (3) of FIG. 1 and FIG. 2, intersection points a, b and c are obtained according to the Bezier curve ABC, the Bezier curve BCA and the Bezier curve CAB.

Alternatively, for example, as shown in (1) to (4) of FIG. 3, a Bezier curve ABC, a Bezier curve BCD, a Bezier curve CDA and a Bezier curve DAB can be obtained in sequence. As shown in (4) of FIG. 3 and FIG. 4, intersection points a, b, c and d are obtained according to the Bezier curve ABC, the Bezier curve BCD, the Bezier curve CDA and the Bezier curve DAB.

Alternatively, for another example, as shown in (1) to (5) of FIG. 5, a Bezier curve ABCD, a Bezier curve BCDE, a Bezier curve CDEA, a Bezier curve DEAB and a Bezier curve EABC can be obtained in sequence. As shown in FIG. 6, some intersection points a, b, c, d and e are selected according to the Bezier curve ABCD, the Bezier curve BCDE, the Bezier curve CDEA, the Bezier curve DEAB and the Bezier curve EABC. Alternatively, as shown in FIG. 7, some intersection points a, b, c, d, e, h, i, g and k are selected according to a Bezier curve ABCD, a Bezier curve BCDE, a Bezier curve CDEA, a Bezier curve DEAB and a Bezier curve EABC.

In some embodiments, the preset polygon 110 does not have parallel sides, for example, as shown in FIG. 1, FIG. 3 or FIG. 5, none of the triangle, the quadrangle and the pentagon has any two parallel sides, and in this way, the irregularity of a final electrode profile 10 can be improved.

In some embodiments, the radii of curvature of respective curvature circles of two adjacent curve segments at the same connection point are equal. Thus, a sharp corner at the intersection point (i.e. the connecting point of two curve segments) of two curve segments can be avoided, which helps to improve the performance of a resonator and also facilitates processing. For example, in FIG. 2, the first middle line segment 11 and the second middle line segment 12 are tangent to each other at the intersection point b, so that the radii of curvature of respective curvature circles of the first middle line segment 11 and the second middle line segment 12 at the point b are equal. By the same reasoning, the two curve segments at the points c and a also satisfy the characteristics of tangency. FIGS. 4, 6 and 7 show the same principle.

In some embodiments, the electrode profile 10 does not have a concave edge. So that an electromechanical coupling factor of a resonator can be increased.

In some embodiments, when the order of the Bezier curves is greater than 2, the number of the plurality of curve segments is equal to or greater than the number of the plurality of Bezier curves. When the order of the Bezier curves is relatively high, the number of intersection points on the same Bezier curve may be greater than 2, and thus the number of middle line segments provided by the same Bezier curve may be greater than 1. Finally, two or more line segments may be selected from the middle line segments provided by the same Bezier curve to serve as the curve segments. For example, in FIGS. 5 and 6, the Bezier curve ABCD provides an eighth middle line segment 18 and a ninth middle line segment 19 to serve as the curve segments.

In some embodiments, when the order of the Bezier curves is equal to 2, the number of the plurality of curve segments is equal to the number of the plurality of Bezier curves. In other words, when the order of the Bezier curves is equal to 2, one curve segment can be intercepted from each Bezier curve. As shown in FIG. 1, one curve segment is intercepted from the three second-order Bezier curves, respectively. As shown in FIG. 2, one curve segment is intercepted from the four second-order Bezier curves, respectively.

In some embodiments, when the preset polygons 110 in the embodiments above are determined, with reference to FIG. 1, FIG. 3 or FIG. 5, a plurality of line segments are diverged outwards in the direction of rays by using a point o as a central point, and one endpoint of each of the line segments is the point o, and another endpoint of the each of the line segments is away from the point o. For example, in FIG. 1, three line segments are diverged outwards from the point o to form line segments oA, oB and oC, respectively, then points A, B and C are sequentially connected in a clockwise or counterclockwise direction to form a triangle, and the triangle is used as one of the preset polygons 110. The quadrangle in FIG. 3 and the pentagon in FIG. 5 show the same principle.

The content above merely relates to preferred embodiments of the present disclosure and is not intended to limit some embodiments of the present disclosure. For a person skilled in the art, some embodiments of the present disclosure may have various modifications and variations. Any modifications, equivalent replacements, improvements, etc. made within the spirit and principle of some embodiments of the present disclosure shall all belong to the scope of protection of the present disclosure.

What is claimed is:

1. A bulk acoustic resonator, comprising a substrate, and a bottom electrode, a piezoelectric layer and a top electrode laminated on the substrate in sequence, at least one of the bottom electrode and the top electrode having orthographic projections on the substrate, a profile of the orthographic projection being formed by sequentially connecting a plurality of curve segments end to end, the plurality of curve segments all being intercepted from line segments near non-endpoints of a plurality of Bezier curves, and an order of the Bezier curves being equal to or greater than 2.

2. The bulk acoustic resonator according to claim 1, wherein each of the Bezier curves comprises a start control point, at least one intermediate control point and an end control point, the start control point, the intermediate control points and the end control point of each of the Bezier curves are all some or all vertices of a preset polygon, and the start control points of the plurality of Bezier curves are sequentially selected from all the vertices of the preset polygon.

3. The bulk acoustic resonator according to claim 2, wherein the preset polygon does not have parallel sides.

4. The bulk acoustic resonator according to claim 1, wherein radii of curvature of respective curvature circles of two adjacent curve segments at a same connection point are equal.

5. The bulk acoustic resonator according to claim 1, wherein when the order of the Bezier curves is greater than 2, the number of the plurality of curve segments is equal to or greater than the number of the plurality of Bezier curves.

6. The bulk acoustic resonator according to claim 1, wherein when the order of the Bezier curves is equal to 2, the number of the plurality of curve segments is equal to the number of the plurality of Bezier curves.

7. An electrode design method for a bulk acoustic resonator, the method comprising:
acquiring a plurality of Bezier curves intersecting with each other and intersection points in the plurality of Bezier curves, wherein the intersection points do not comprise endpoints of the Bezier curves, and the order of the Bezier curves is equal to or greater than 2;
determining line segments near non-endpoints of the Bezier curves according to the intersection points; and
selecting, from the line segments near the non-endpoints of the plurality of Bezier curves, some or all of the line segments near the non-endpoints that are sequentially connected end to end at the intersection points to serve as a plurality of curve segments, such that the plurality of curve segments are sequentially connected end to end to form an electrode profile.

8. The electrode design method according to claim 7, wherein acquiring the plurality of Bezier curves intersecting with each other and the intersection points in the plurality of Bezier curves comprises:
acquiring a preset polygon and vertices of the preset polygon;
selecting some or all vertices of the preset polygon to serve as a start control point, at least one intermediate control point and an end control point of each of the Bezier curves, the start control points of the plurality of the Bezier curves being sequentially selected from all the vertices of the preset polygon; and
constructing a plurality of Bezier curves intersecting with each other according to the start control point, the at least one intermediate control point and the end control point of each of the Bezier curves, and determining intersection points in the plurality of Bezier curves.

9. The electrode design method according to claim 8, wherein the preset polygon does not have parallel sides.

10. The electrode design method according to claim 7, wherein radii of curvature of respective curvature circles of two adjacent curve segments at the same connection point are equal.

11. The electrode design method according to claim 7, wherein a formula of the Bezier curves is:
$$B ( t ) = {\sum }_{i = 0}^{n} ( \begin{matrix}n \\ i\end{matrix} ) {{P}_{i} ( 1 - t )}^{n - i} {t}^{i} , \\ where ( \begin{matrix}n \\ i\end{matrix} ) = \frac{n !}{i ! ( n - 1 ) !} , t ∈ [ 0 , 1 ] ,$$
Pᵢ represents control points of the Bezier curves, and n represents the order control number of the Bezier curves.

12. The electrode design method according to claim 11, wherein Pᵢ represents the control points of the Bezier curves, and a Bezier polygon is formed by connecting the control points of the Bezier curves with lines, and starts at P₀ and ends at Pₙ.

13. The electrode design method according to claim 8, wherein the order of the Bezier curves is 2, and a formula of the Bezier curves is: B(t)=(1−t)²P₀+2t(1−t)²P₁+t²P₂, where t∈[0,1], P₀ represents the start control point, P₁ represents the intermediate control point, and P₂ represents the end control point.

14. The electrode design method according to claim 8, wherein the order of the Bezier curves is 3, and a formula of the Bezier curves is: B(t)=(1−t)³P₀+3t(1−t)²P₁+3t²(1−t)P₂+t³P₃, where t∈[0,1], P₀ represents the start control point, P₁ and P₂ represent the intermediate control points, and P₃ represents the end control point.

15. The electrode design method according to claim 7, wherein determining the line segments near the non-endpoints of the Bezier curves according to the intersection points comprises:
intercepting, from the Bezier curves, at least one line segment near the non-endpoints using two adjacent intersection points, wherein each of the line segments near the non-endpoints does not comprise a line segment having the endpoints in the Bezier curves.

16. The electrode design method according to claim 7, wherein the electrode profile does not have concave edges.

17. The electrode design method according to claim 8, further comprising:
diverging a plurality of line segments outwards in the direction of rays by using a point o as a central point, one endpoint of each of the line segments is the point o, and another endpoint of the each of the line segments is away from the point o; and
sequentially connecting the endpoints of the plurality of line segments away from the point o in a clockwise or counterclockwise direction.

18. The electrode design method according to claim 17, further comprising: diverging three line segments outwards from the point o to form line segments oA, oB and oC, respectively, and then sequentially connecting points A, B and C in a clockwise or counterclockwise direction to form a triangle, the triangle being used as one of the preset polygons.

19. The bulk acoustic resonator according to claim 1, wherein a formula of the Bezier curves is:
$$B ( t ) = {\sum }_{i = 0}^{n} ( \begin{matrix}n \\ i\end{matrix} ) {{P}_{i} ( 1 - t )}^{n - i} {t}^{i} , \\ where ( \begin{matrix}n \\ i\end{matrix} ) = \frac{n !}{i ! ( n - 1 ) !} , t ∈ [ 0 , 1 ] ,$$
Pᵢ represents control points of the Bezier curves, and n represents the order control number of the Bezier curves.

20. The bulk acoustic resonator according to claim 2, wherein the order of the Bezier curves is 2, and a formula of the Bezier curves is: B(t)=(1−t)²P₀+2t(1−t)²P₁+t²P₂, where t∈[0,1], P₀ represents the start control point, P₁ represents the intermediate control point, and P₂ represents the end control point.
